(19) United States
(12) Patent Application Publication
(10) Pub. No.: US 2023/0411203 A1
(43) Pub. Date: Dec. 21, 2023

(54) APPARATUS FOR PROCESSING SUBSTRATE

(71) Applicant: EUGENE TECHNOLOGY CO., LTD., Yongin-si (KR)

(72) Inventors: Ryong HWANG, Yeoju-si (KR); Se Jong SUNG, Yongin-si (KR); Woong Joo JANG, Suwon-si (KR); Yang Sik SHIN, Yongin-si (KR); Woo Duck JUNG, Suwon-si (KR)

(73) Assignee: EUGENE TECHNOLOGY CO., LTD., Yongin-si (KR)

(21) Appl. No.: 18/456,589

(22) Filed: Aug. 28, 2023

Related U.S. Application Data
(63) Continuation of application No. 17/423,687, filed on Jul. 16, 2021.

(30) Foreign Application Priority Data
Jan. 18, 2019 (KR) 10-2019-0006953

(51) Int. Cl. H01L 21/687; C23C 16/30; C23C 16/50; H01J 37/32

(52) U.S. Cl. CPC H01L 21/68735; C23C 16/308; H01L 21/0214; H01J 37/32724; H01J 37/32834; C23C 16/50

(57) ABSTRACT

In accordance with an exemplary embodiment of the present invention, provided is an apparatus for processing substrate, the apparatus comprising: a chamber providing a process space formed therein; a susceptor on which a substrate is placed, the susceptor being installed in the process space; a gas supply port formed in the central portion of the ceiling of the chamber to supply a source gas to the process space; an exhaust port formed on a side wall of the chamber to be positioned outside and below the susceptor, the exhaust port exhausting a gas in the process space in the direction from a center of the susceptor toward an edge of the susceptor; and an antenna positioned above the susceptor and installed outside the chamber to generate plasma from the source gas, an upper surface of the susceptor comprises a seating surface on which the substrate is placed during the process and a control surface which is located on the periphery of the seating surface and faces the process space to be exposed to the plasma during process, the control surface being positioned lower than the seating surface.

### TECHNICAL FIELD

The present disclosure relates to an apparatus for processing substrate, and more specifically, to an apparatus for processing substrate capable of improving the uniformity of a process for a substrate.

### BACKGROUND ART

A thin gate dielectric of SiO2 has several problems. For example, boron from the boron-doped gate electrode can penetrate through the thin gate dielectric of SiO2 into the underlying silicon substrate. Also, typically thin dielectric has increased gate leakage, ie tunneling, which increases the amount of power dissipated by the gate.

One way of solving the problem is to incorporate nitrogen into the SiO2 layer to form the SiOxNy gate dielectric. Incorporation of nitrogen into the SiO2 layer blocks boron penetrating into the underlying silicon substrate and increases the dielectric constant of the gate dielectric, allowing the use of a thicker dielectric layer.

Heating a silicon oxide layer in the presence of ammonia (NH3) has been used to convert a SiO2 layer to a SiOxNy layer. However conventional methods of heating a silicon oxide layer in the presence of NH3 in a furnace typically result in non-uniform addition of nitrogen to the SiO2 layer in different parts of the furnace due to air flow when the furnace is open or closed. Additionally, oxygen of the SiO2 layer or vapor contamination can block the addition of nitrogen to the SiO2 layer.

Plasma nitridation (DPN, decoupled plasma nitridation) has also been used to convert SiO2 layers to SiOxNy layers.

### DISCLOSURE

### Technical Problem

An object of the present invention is to provide an apparatus for processing substrate capable of improving the uniformity of a process for the entire surface of a substrate.

Another object of the present invention is to provide an apparatus for processing substrate capable of improving a process rate for an edge surface of a substrate.

Other objects of the present invention will become clearer by the following detailed description and the accompanying drawings.

### SUMMARY

In accordance with an exemplary embodiment of the present invention, provided is an apparatus for processing substrate, the apparatus comprising: a chamber providing a process space formed therein; a susceptor on which a substrate is placed, the susceptor being installed in the process space; a gas supply port formed in the central portion of the ceiling of the chamber to supply a source gas to the process space; an exhaust port formed on a side wall of the chamber to be positioned outside and below the susceptor, the exhaust port exhausting a gas in the process space in the direction from a center of the susceptor toward an edge of the susceptor; and an antenna positioned above the susceptor and installed outside the chamber to generate plasma from the source gas, an upper surface of the susceptor comprises a seating surface on which the substrate is placed during the process and a control surface which is located on the periphery of the seating surface and faces the process space to be exposed to the plasma during process, the control surface being positioned lower than the seating surface.

The seating surface may have a shape corresponding to the substrate, and the control surface is ring-shaped.

The width of the control surface may be 20 to 30 mm.

The height difference between the seating surface and the control surface may be 4.35 to 6.35 mm.

The distance between the lower end of the antenna and the seating surface may be 93 to 113 mm.

The antenna may be installed in a spiral shape along the vertical direction around the outer periphery of the chamber.

The chamber may comprise: a lower chamber in which the susceptor is installed, an upper portion of the lower chamber is opened and a passage through which the substrate enters and exits is formed on a side wall of the lower chamber; and an upper chamber connected to the upper portion of the lower chamber, the antenna being installed on the outer periphery of the upper chamber, wherein an inner diameter of the upper chamber corresponds to an outer diameter of the susceptor, and a cross-sectional area of the upper chamber is smaller than a cross-sectional area of the lower chamber.

The apparatus may further comprise: one or more exhaust plates installed in the process space and positioned around the susceptor so as to be lower than the upper surface of the susceptor, the exhaust plates being positioned parallel to the upper surface of the susceptor and having a plurality of exhaust holes.

The susceptor may comprise: a heater that is heated using electric power supplied; an upper cover covering an upper portion of the heater and having the seating surface and the control surface; and a side cover connected to the upper cover and covering a side of the heater.

### Advantageous Effects

According to an embodiment of the present invention, the uniformity of a process for the entire surface of a substrate can be improved. In particular, it is possible to improve the process rate for the edge surface of the substrate, thereby increasing the nitrogen concentration in the edge portion of the substrate.

### DESCRIPTION OF DRAWINGS

FIG. 1 shows an apparatus for processing substrate schematically according to an embodiment of the present invention.

FIG. 2 shows the susceptor in FIG. 1.

FIGS. 3 and 4 shows process uniformity according to an embodiment of the present invention.

### BEST MODE

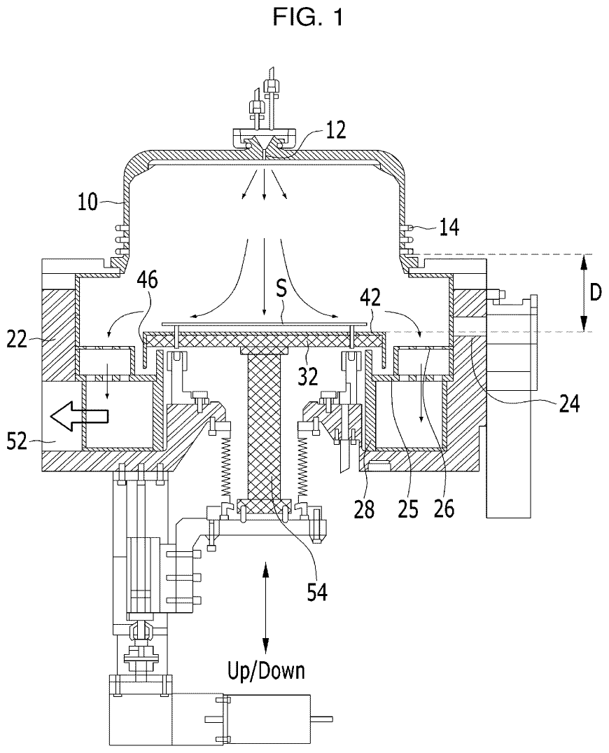

Hereinafter, preferred embodiments of the present invention will be described in more detail with reference to the accompanying FIG. 1 to FIG. 4. Embodiments of the present invention may be modified into various forms, and the scope of the present invention should not be construed as being limited to the embodiments described below. The present embodiments are provided to more fully describe the present invention to those skilled in the art to which the present invention pertains. Accordingly, the shape of each element shown in the figures may be exaggerated to emphasize a clearer description.

FIG. 1 shows an apparatus for processing substrate schematically according to an embodiment of the present invention. As shown in FIG. 1, the apparatus includes a chamber and a susceptor. The chamber provides a process space formed therein, and a plasma process is performed on the substrate in the process space.

The chamber includes a lower chamber 22 and an upper chamber 10, and the lower chamber 22 has a passage 24 formed on a side wall and an exhaust port 52 formed on the other side wall, and an upper portion of the lower chamber is opened. The substrate S may enter or be withdrawn from the process space through the passage 24, and gas in the process space may be discharged through the exhaust port 52.

The upper chamber 10 is connected to the opened upper portion of the lower chamber 22 and has a dome shape. The upper chamber 10 has a gas supply port 12 formed in the central portion of the ceiling, and a source gas or the like may be supplied into the process space through the gas supply port 12. Cross-sections of the upper chamber 10 and the lower chamber 22 may have shapes corresponding to the shape (eg, circular) of the substrate, and the cross-sectional area of the upper chamber 10 may be larger than the cross-sectional area of the lower chamber 22. The centers of the upper chamber 10 and the lower chamber 22 are installed to substantially coincide with the center of the susceptor to be described later, and the inner diameter of the upper chamber 10 may substantially coincide with the outer diameter of the susceptor.

The antenna 14 is installed in a spiral shape along the vertical direction around the outer periphery of the upper chamber 10 (ICP type), and can generate plasma from the source gas supplied from the outside. The antenna 14 is installed on the upper chamber 10 located above the susceptor to the described later, and plasma is generated inside the upper chamber 10 and moves to the lower chamber 22 to react with the substrate S.

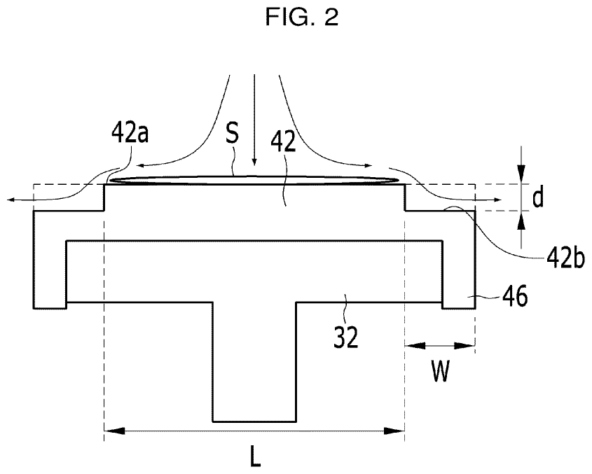

FIG. 2 shows the susceptor in FIG. 1. The susceptor is installed inside the lower chamber 22, and the process proceeds in a state where the substrate S is placed on the upper surface of the susceptor. The susceptor includes a heater 32 and heater covers 42 and 46, and the heater covers 42 and 46 are installed so as to surround the top and sides of the heater.

Specifically, the heater 32 is heated using electric power supplied from the outside to heat the substrate to a process temperature, and has a circular disk shape and is supported through a support shaft 54 connected to the center of the heater to be placed in the lower chamber 22. Unlike this embodiment, the heater 32 may be replaced with a cooling plate that can be cooled using a refrigerant or the like. The heater covers 42 and 46 include a disk-shaped upper cover 42 covering the upper portion of the heater 32 and a side cover 46 covering the side of the heater 32, the upper cover 42 and the side cover 46 are connected to each other.

The upper surface of the upper cover 42 has a seating surface 42a and a control surface 42b. The substrate S is exposed to plasma in a state placed on the seating surface 42a and performed in the process, the seating surface 42a has a larger diameter than the substrate S. For example, when the diameter of the substrate S is 300 mm, the diameter L of the seating surface 42a may be 305˜310 mm. The seating surface 42a is disposed in a generally horizontal state. The control surface 42h is located lower than the seating surface 42a so that a ring-shaped flow space (indicated by a dotted line in FIG. 2) is formed on the outside of the seating surface 42a and the upper portion of the control surface 42b, the control surface 42b has a ring shape disposed on the periphery of the seating surface 42a and the width W is 20 to 30 mm. The control surface 42b directly faces the process space and is exposed to plasma during the process of the substrate S, and may be parallel to the seating surface 42a. However, unlike this embodiment, it can be inclined inwardly and/or outwardly.

Referring to FIG. 1, a plurality of exhaust plates 25 and 26 are vertically disposed around the susceptor, and installed at a height lower than the upper surface of the susceptor. The exhaust plates 25 and 26 have a plurality of exhaust holes and are generally horizontally disposed. The exhaust plates 25 and 26 may be supported by a support mechanism 28. For example, when an exhaust pump (not shown) is connected to the exhaust port 52 to start forced exhaust, the exhaust pressure is generally uniformly distributed in the process space through the exhaust plates 25 and 26 (regardless of the position of the exhaust port), as shown in FIGS. 1 and 2, the flow of plasma is uniformly formed in the direction from the center of the substrate S along the surface of the substrate S toward the edge of the substrate S, by-products and the like through the plasma process may be uniformly exhausted along th direction.

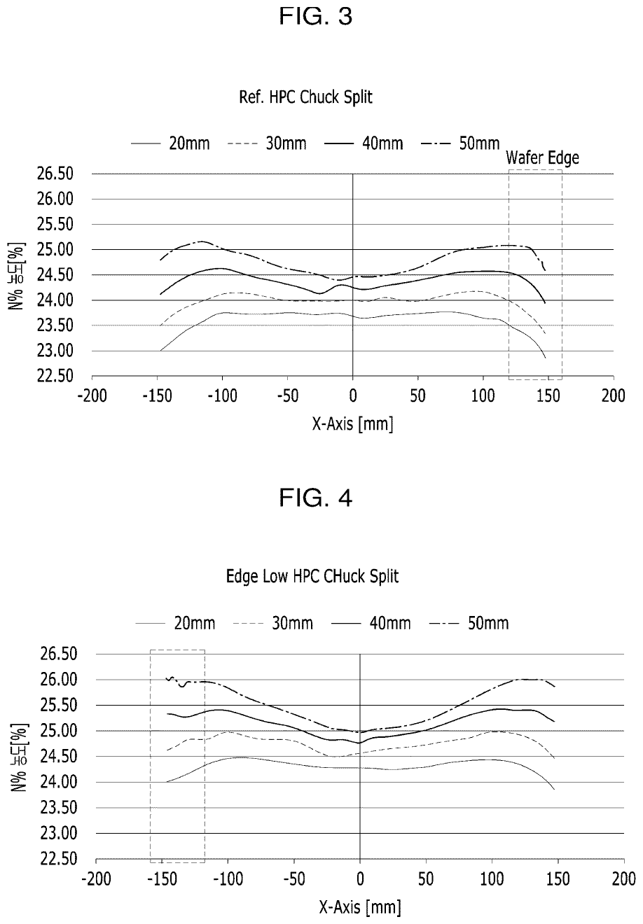

FIGS. 3 and 4 shows process uniformity according to an embodiment of the present invention. As described above, after the SiO2 layer is deposited on the substrate S by about 20 to 30 Å, the substrate S is exposed to plasma to form a SiOxNy gate dielectric(plasma nitridation (PN)). The nitrogen source may be nitrogen (N2), NH3, or a combination thereof, and the plasma may further include an inert gas such as helium, argon, or a combination thereof. While the substrate S is exposed to the plasma (50 to 100 seconds, preferably about 50 seconds), the pressure may be about 15 mTorr and the temperature may be about 150° C. (the pressure can be adjusted in the range of 15 to 200 mTorr, the temperature can be adjusted in the range of room temperature to 150° C.) Optionally, the substrate S is annealed in a state in which 02 is supplied after plasma exposure, and may be annealed at a temperature of about 800° C. for about 15 seconds.

On the other hand, plasma nitridation (DPN, decoupled plasma nitridation) has been used to form the SiOxNy gate dielectric, but the nitrogen concentration was non-uniformly distributed on the surface of the substrate after nitridation, especially the nitrogen concentration in the edge portion of the substrate S was significantly lowered.

As a way to improve this, the separation distance between the seating surface of the susceptor and the lower end of the antenna (D in FIG. 1) was adjusted, but the effect was limited. Referring to FIG. 1, the susceptor is supported by the support shaft 54, and the support shaft 54 is elevating by a lifting mechanism, so the distance between the susceptor and the antenna 14 can be adjusted by movement of the susceptor using the lifting mechanism.

As a result of adjusting the movement distance (Chuck [mm]) of the susceptor to 20˜50 mm, the distance (D) between the susceptor and the antenna is shown in Table 1 below, and as shown in Table 2 below, the process uniformity varies from 1.30˜1.90, and the lowest value was 1.30 (corresponding to Ref. HPC).

TABLE 1

| Chuck[mm] | D[mm] |
|---|---|
| 0 | 133 |
| 10 | 123 |
| 20 | 113 |
| 30 | 103 |
| 40 | 93 |
| 50 | 83 |

TABLE 2

| | | | Ref. HPC | | | Edge Low HPC | | | |
|---|---|---|---|---|---|---|---|---|---|
| | | | N % concentration @X scan | | | N % concentration @X scan | | | |
| | | Chuck | Ave | Range | Unif | Ave | Range | Unif | |
| Item | Process | (mm) | (Å) | (Å) | (%) | (Å) | (Å) | (%) | Remark |
| Chuck | Plasma | 20 | 23.41 | 0.89 | 1.90 | 24.20 | 0.60 | 1.25 | N % |
| Split | Nitridation | 30 | 23.83 | 0.81 | 1.69 | 24.72 | 0.47 | 0.96 | concentration |
| | | 40 | 24.32 | 0.63 | 1.30 | 25.21 | 0.63 | 1.24 | measurement |
| | | 50 | 24.84 | 0.75 | 1.52 | 25.71 | 1.13 | 2.20 | |

Therefore, an additional method was sought to further improve this, so that a control surface 42b is installed on the upper surface of the susceptor (or heater cover) and the control surface 42b is lower than the seating surface 42a (the difference in height between the control surface and the seating surface is 6.35 mm). As a result, as shown in Table 2, it can be seen that the process uniformity varies from 0.96 to 2.20, and the lowest value was 0.96 (corresponding to Edge Low HPC). In particular, when the separation distance between the seating surface 42a of the susceptor and the lower end of the antenna 14 was 103 mm, it was confirmed that the process uniformity before and after improvement was significantly improved from 1.69 to 0.96.

As a result of various studies on the reasons for the improvement of process uniformity, plasma shielding can be minimized by suppressing the formation of a plasma sheath at the edge portion of the substrate S, and through this, it is possible to prevent the nitrogen concentration from lowering in the edge portion of the substrate S. Specifically, when the control surface 42b described above is lower than the seating surface 42a, the portion of the active species (N radicals and ions) participated in plasma nitridation is greater than the consumed portion of the active species at the edge portion of the substrate S. However, when the control surface 42b is parallel to or higher than the seating surface 42a, the consumed portion of the active species is greater than the participated portion of the active species at the edge portion of the substrate S. Therefore, it is thought that process uniformity can be improved if the control surface 42b is positioned lower than the seating surface 42a.

Referring to FIG. 3, it can be seen that, when a plasma process is performed by a conventional susceptor, the nitrogen concentration in the edge portion of the substrate S is remarkably reduced, and the graph has an ‘M’ shape. On the other hand, referring to FIG. 4, when the plasma process by the susceptor using the control surface 42b is performed, it can be seen that the nitrogen concentration in the edge portion of the substrate S is sufficiently improved, and the graph is a ‘V’ shape.

Tables 3 and 4 show the degree of improvement in process uniformity according to the distance between the susceptor and the antenna and the height difference between the control surface and the seating surface. On the other hand, the width of the control surface is preferably 20 to 30 mm so as not to affect the plasma process, the following content is based on 25 mm.

TABLE 3

| | Edge Low HPC | | | | | | Ref.HPC | | | |
|---|---|---|---|---|---|---|---|---|---|---|
| | 6.35 mm | | | 4.35 mm | | | 0 mm | | | |
| | N % concentration @X | | | N % concentration @X | | | N % concentration @X | | | |
| | scan | | | scan | | | scan | | | |
| Item | Ave | Range | Unif | Ave | Range | Unif | Ave | Range | Unif | |
| Chuck | (Å) | (Å) | (%) | (Å) | (Å) | (%) | (Å) | (Å) | (%) | Remark |
| 20 mm | 24.15 | 0.70 | 1.44 | 24.72 | 0.56 | 1.14 | 24.37 | 0.94 | 1.92 | N % |
| 30 mm | 24.61 | 0.53 | 1.09 | 25.08 | 0.42 | 0.83 | 24.83 | 0.76 | 1.53 | concentration |
| 40 mm | 25.05 | 0.94 | 1.87 | 25.47 | 0.68 | 1.33 | 25.32 | 0.64 | 1.26 | measurement |
| 50 mm | 25.62 | 1.15 | 2.25 | 25.95 | 1.10 | 2.12 | 25.83 | 0.74 | 1.44 | |

TABLE 4

| | Edge Low HPC | | | | | | Ref. HPC | | | |
|---|---|---|---|---|---|---|---|---|---|---|
| | 3.35 mm | | | 2.35 mm | | | 0 mm | | | |
| | N % concentration @X | | | N % concentration @X | | | N % concentration @X | | | |
| | scan | | | scan | | | scan | | | |
| Item | Ave | Range | Unif | Ave | Range | Unif | Ave | Range | Unif | |
| Chuck | (Å) | (Å) | (%) | (Å) | (Å) | (%) | (Å) | (Å) | (%) | Remark |
| 20 mm | 23.50 | 0.61 | 1.31 | 24.57 | 0.76 | 1.54 | 24.37 | 0.94 | 1.92 | N % |
| 30 mm | 24.24 | 0.59 | 1.22 | 24.92 | 0.88 | 1.77 | 24.83 | 0.76 | 1.53 | concentration |
| 40 mm | 24.78 | 0.73 | 1.48 | 25.55 | 0.62 | 1.22 | 25.32 | 0.64 | 1.26 | measurement: |
| 50 mm | 25.32 | 1.18 | 2.33 | 26.03 | 1.06 | 2.04 | 25.83 | 0.74 | 1.44 | SKH, |
| | | | | | | | | | | R3 |
| | | | | | | | | | | Aleris |

Referring to Tables 3 and 4, the optimal height difference between the control surface 42b and the seating surface 42a is different depending on the distance between the susceptor and the antenna 14. For example, when the moving distance is (distance D=103 mm), it can be seen that the optimal height difference with the lowest process uniformity is 4.35 mm (process uniformity 0.83), and when the moving distance is 20 mm (distance D=113 mm), it can be seen that the optimal height difference with the lowest uniformity is 4.35 mm (process uniformity 1.14). However, when the moving distance is 40 mm (distance D=93 min), it can be seen that the optimum height difference with the lowest process uniformity is 2.35 mm (process uniformity 1.22).

Although the present invention has been described with reference to the specific embodiments, the present invention is not limited thereto. Therefore, it will be readily understood by those skilled in the art that various modifications and changes can be made thereto without departing from the spirit and scope of the present invention defined by the appended claims.

### INDUSTRIAL APPLICABILITY

The present invention can be applied to various types of semiconductor manufacturing facilities and manufacturing methods.

What is claimed is:

1. A method of processing a substrate using a chamber providing a process space formed therein and a susceptor on which the substrate is placed, and an antenna positioned above the susceptor and installed outside the chamber to generate plasma from a source gas, wherein an upper surface of the susceptor comprises a seating surface on which the substrate is placed during the process and a control surface which is located on the periphery of the seating surface and faces the process space to be exposed to the plasma during process, the control surface being positioned lower than the seating surface, the method comprising:
defining the difference in height between the control surface and the seating surface as X, the separation distance between the seating surface of the susceptor and the lower end of the antenna as Y;
measuring the uniformity of processing a substrate using the plasma by combining X and Y; and
processing a substrate using the plasma after setting the values of X and Y based on a case where the uniformity is the lowest.

2. The apparatus of claim 1, wherein the seating surface has a shape corresponding to the substrate, and the control surface is ring-shaped.

3. The apparatus of claim 2, wherein the width of the control surface is 20 to 30 mm.

4. The apparatus of claim 1, wherein the antenna is installed in a spiral shape along the vertical direction around the outer periphery of the chamber.

5. The apparatus of claim 1, wherein the chamber comprises:
a lower chamber in which the susceptor is installed, an upper portion of the lower chamber is opened and a passage through which the substrate enters and exits is formed on a side wall of the lower chamber; and
an upper chamber connected to the upper portion of the lower chamber, the antenna being installed on the outer periphery of the upper chamber,
wherein an inner diameter of the upper chamber corresponds to an outer diameter of the susceptor, and a cross-sectional area of the upper chamber is smaller than a cross-sectional area of the lower chamber.

6. The apparatus of claim 1, wherein the susceptor comprises:
a heater that is heated using electric power supplied;
an upper cover covering an upper portion of the heater and having the seating surface and the control surface; and
and a side cover connected to the upper cover and covering a side of the heater.
